(19) United States
(12) Patent Application Publication
(10) Pub. No.: US 2020/0318941 A1
(43) Pub. Date: Oct. 8, 2020

(54) Device and Method for Detecting Film Thickness

(71) Applicant: WEIHAI HUALING OPTO-ELECTRONICS CO.,LTD., Shandong (CN)

(72) Inventors: Li JIANG, Shandong (CN); Yonghui LIN, Shandong (CN); Xiumei QI, Shandong (CN); Mingfeng SUN, Shandong (CN)

(21) Appl. No.: 16/300,965

(22) PCT Filed: Oct. 27, 2017
(86) PCT No.: PCT/CN2017/108087

§ 371 Date: Nov. 13, 2018

(30) Foreign Application Priority Data
Feb. 28, 2017 (CN) 201710115068.8

(51) Int. Cl. G01B 7/06; G07D 7/026; G07D 7/164; G01R 19/00

(52) U.S. Cl. CPC G01B 7/087; G01R 19/0084; G07D 7/164; G07D 7/026

(57) ABSTRACT

A device and method for detecting a film thickness are provided. The device includes: a common electrode, a detection electrode, a common electrode voltage generating circuit, and a detection electrode signal processing circuit. A detection channel for a film to be detected is formed between a first common surface and a first detection surface. The common electrode voltage generating circuit is configured to generate a voltage on the common electrode, as to induce an effective signal voltage on the detection electrode. The detection electrode signal processing circuit includes: a reset voltage time sequence control circuit, a time sequence control circuit for transferring the effective signal voltage on the detection electrode and a differential amplifier.

### TECHNICAL FIELD

The present disclosure relates to the field of digital detection, in particular to a device and method for detecting a film thickness.

### BACKGROUND

As all we known, online continuous thickness measurement of sheet-like objects, such as a paper, a bill, a plastic film, and textile becomes more and more important in the process of producing, detecting, processing and recycling the corresponding products of the sheet-like objects. In recent years, a technology of detecting a film thickness through an electrostatic induction between electrodes is in continuous research and exploration; for example, a capacitive paper thickness sensor in the related art mainly converts a capacitance change of a capacitor into an oscillation frequency change of the capacitor, and then converts a frequency change into a voltage change through a frequency-voltage conversion component. Moreover, a method for detecting a material thickness in the related art mainly measures, by using an electrode plate of a plate capacitor as a sensitive device for thickness detection, a displacement of the active electrode plate of the capacitor caused by a thickness change of an object, to cause the capacitance of the plate capacitor to change. Moreover, in the related art, a common electrode and a detection electrode which are opposite to each other are also adopted to form a detection channel; when an object to be detected goes through the detection channel, a dielectric constant of a medium between the common electrode and the detection electrode changes, correspondingly the number of charges induced on the detection electrode changes, and the value of an output voltage on the detection electrode also changes. With the difference of the thickness of the detected object, the dielectric constants of the medium between the common electrode and the detection electrode are different, and then the numbers of charges induced on the detection electrode are different, and the values of the output voltages on the detection voltage are different. Therefore, the thickness of the detected object may be calculated by analyzing and processing the value of a voltage signal of the detection electrode.

However, in the process of detecting a film thickness, when a device for detecting a film thickness is interfered by external environments (for example, temperature, noise, humidity and electromagnetic field), signals in the above several detecting ways will distort, which will influence the accuracy of thickness detection.

Aiming at the problem in the related art that the device for detecting a film thickness is easy to be interfered by environments, an effective solution has not been presented.

### SUMMARY

The present disclosure provides a device and method for detecting a film thickness, so as to at least solve the technical problem in the related art that the device for detecting a film thickness is easy to be interfered by environments.

According to an aspect of the present disclosure, a device for detecting a film thickness is provided. The device includes: a common electrode, a detection electrode, a common electrode voltage generating circuit, and a detection electrode signal processing circuit. The common electrode and the detection electrode are set oppositely and at interval in a first direction. A first common surface of the common electrode is opposite to a first detection surface of the detection electrode. A detection channel for a film to be detected is formed between the first common surface and the first detection surface. Herein, the common electrode voltage generating circuit is configured to generate a voltage on the common electrode, as to induce an effective signal voltage on the detection electrode. The detection electrode signal processing circuit includes: a reset voltage time sequence control circuit, a time sequence control circuit for transferring the effective signal voltage on the detection electrode and a differential amplifier. The reset voltage time sequence control circuit is configured to control the detection electrode to reset a voltage. The time sequence control circuit for transferring the effective signal voltage on the detection electrode is configured to transfer the effective signal voltage on the detection electrode. The differential amplifier is configured to, after performing differential amplification on a reset voltage and the effective signal voltage on the detection electrode, output an effective signal used for detecting the film to be detected.

In at least one alternative embodiment, the device further includes: a common electrode voltage time sequence control circuit. The common electrode voltage time sequence control circuit is configured to generate a control signal. The control signal is used for controlling a voltage amplitude and a voltage width, which are applied to the common electrode by the common electrode voltage generating circuit, to adapt to a detection of a predetermined signal.

In at least one alternative embodiment, the detection electrode signal processing circuit further includes: a time sequence control circuit for transferring the reset voltage on the detection electrode, configured to, after the detection electrode resets the voltage, transfer the reset voltage on the detection electrode.

In at least one alternative embodiment, the detection electrode signal processing circuit further includes: a shifting time sequence control circuit, configured to transmit the reset voltage and the effective signal voltage on the detection electrode to two input ends of the differential amplifier.

In at least one alternative embodiment, the device further includes: a common electrode substrate and a detection electrode substrate. The common electrode is set on a first surface of the common electrode substrate, and the first surface of the common electrode substrate is vertical to the first direction. The common electrode voltage generating circuit is set on a second surface of the common electrode substrate. The detection electrode substrate and the common electrode substrate are set at interval in the first direction. A first surface of the detection electrode substrate faces the first surface of the common electrode substrate, and is parallel to the first surface of the common electrode substrate. The detection electrode is set on the first surface of the detection electrode substrate. The detection electrode signal processing circuit is set on a second surface of the detection electrode substrate.

In at least one alternative embodiment, the device further includes: a common electrode frame and a detection electrode frame. The common electrode substrate is set on the common electrode frame. The detection electrode frame and the common electrode frame are set at interval in the first direction. The detection electrode substrate is set on the detection electrode frame.

In at least one alternative embodiment, the device further includes: a common electrode protection layer and a detection electrode protection layer. The common electrode protection layer is set on a surface of the common electrode. The detection electrode protection layer is set on a surface of the detection electrode.

In at least one alternative embodiment, the device further includes: a common electrode conduction film and a detection electrode conduction film. The common electrode conduction film is set between the common electrode and the common electrode protection layer. The detection electrode conduction film is set between the detection electrode and the detection electrode protection layer.

In at least one alternative embodiment, there are multiple detection electrodes. The multiple detection electrodes are set at intervals along a second direction, wherein the second direction is vertical to a moving direction of the film to be detected, and is vertical to the first direction.

In at least one alternative embodiment, the detection electrode is an electrode chip, or the detection electrode is a sensor of sensing a charge.

According to another aspect of the present disclosure, a method for detecting a film thickness is further provided. The method includes that: the common electrode voltage generating circuit generates a voltage on the common electrode, as to induce an effective signal voltage on the detection electrode, wherein the common electrode and the detection electrode are set oppositely and at interval in a first direction, the first common surface of the common electrode is opposite to a first detection surface of the detection electrode, and a detection channel for the film to be detected is formed between the first common surface and the first detection surface; a reset voltage time sequence control circuit in a detection electrode signal processing circuit controls the detection electrode to reset a voltage; and a time sequence control circuit for transferring the effective signal voltage on the detection electrode in the detection electrode signal processing circuit transfers an effective signal voltage on the detection electrode. A differential amplifier in the detection electrode signal processing circuit outputs an effective signal used for detecting a film to be detected after performing differential amplification on the reset voltage and the effective signal voltage on the detection electrode.

In at least one alternative embodiment, in a situation where there are multiple detection electrodes, when the reset voltage on each detection electrode is transmitted on a falling edge of a time sequence for transferring the reset voltage on the detection electrode, the reset voltage time sequence control circuit controls the reset voltage to reset each detection electrode; when the effective signal voltage on each detection electrode is transmitted on the falling edge of a time sequence for transferring the effective signal voltage on the detection electrode, the common electrode voltage generating circuit is controlled, according to a control signal of the common electrode voltage time sequence control circuit, to apply a voltage to the common electrode.

The device for detecting a film thickness of the present disclosure is adopted. The device for detecting the film thickness includes: the common electrode, the detection electrode, the common electrode voltage generating circuit, and the detection electrode signal processing circuit. The common electrode and the detection electrode are set oppositely and at interval in a first direction. A first common surface of the common electrode is opposite to a first detection surface of the detection electrode. A detection channel for a film to be detected is formed between the first common surface and the first detection surface. Herein, the common electrode voltage generating circuit is configured to generate a voltage on the common electrode, as to induce an effective signal voltage on the detection electrode. The detection electrode signal processing circuit includes: the reset voltage time sequence control circuit, the time sequence control circuit for transferring the effective signal voltage on the detection electrode and the differential amplifier. The reset voltage time sequence control circuit is configured to control the detection electrode to reset a voltage. The time sequence control circuit for transferring the effective signal voltage on the detection electrode is configured to transfer the effective signal voltage on the detection electrode. The differential amplifier is configured to output, after performing differential amplification on the reset voltage and the effective signal voltage on the detection electrode, the effective signal used for detecting the film to be detected. According to the device provided in the present disclosure, the technical problem in the related art that the device for detecting a film thickness is easy to be interfered by environments is solved, and the technical effect that the method for detecting a film thickness can avoid environmental interferences is achieved.

### BRIEF DESCRIPTION OF THE DRAWINGS

The accompanying drawings described here are used for providing a deeper understanding of the present disclosure, and constitute a part of the application; schematic embodiments of the present disclosure and description thereof are used for illustrating the present disclosure and not intended to form an improper limit to the present disclosure. In the accompanying drawings:

FIG. 1 is a schematic diagram of a device for detecting a film thickness according to the present disclosure;

FIG. 2 is a structure diagram of a common electrode and a detection electrode of the device for detecting the film thickness according to the present disclosure;

FIG. 3 is a flowchart of a method for detecting a film thickness according to the present disclosure;

FIG. 4 is a signal processing flowchart of the device for detecting the film thickness according to the present disclosure;

FIG. 5 is a signal processing diagram of the device for detecting the film thickness according to the present disclosure; and

FIG. 6 is sequence diagrams of various signals of the device for detecting the film thickness according to the present disclosure.

### DETAILED DESCRIPTION OF THE EMBODIMENTS

In order to make those skilled in the art understand the solutions of the present disclosure better, the technical solutions in the embodiments of the present disclosure are clearly and completely elaborated below in combination with the accompanying drawings. It is apparent that the described embodiments are only a part of the embodiments of the present disclosure but not all. Based on the embodiments of the present disclosure, all the other embodiments obtained by those of ordinary skill in the art on the premise of not contributing creative effort should belong to the protection scope of the present disclosure.

It is to be noted that the terms like “first” and “second” In the specification, the claims and the accompanying drawings of the present disclosure are used for differentiating the similar objects, but do not have to describe a specific order or a sequence. It should be understood that the objects may be exchanged under appropriate circumstances, so that the embodiments of the present disclosure described here may be implemented in an order different from that described or shown here. Moreover, the terms like “include” and “have” and any variation of them are intended to cover nonexclusive including; for example, the process, method, system, product or device including a series of steps or elements do not have to be limited to those clearly listed steps or elements, but may include other steps or elements which are not clearly listed or inherent in these process, method, system, product or device.

### Embodiment 1

According to an aspect of the present disclosure, a device for detecting a film thickness is provided. The device includes: a common electrode, a detection electrode, a common electrode voltage generating circuit, and a detection electrode signal processing circuit. The common electrode and the detection electrode are set oppositely and at interval in a first direction. A first common surface of the common electrode is opposite to a first detection surface of the detection electrode. A detection channel for a film to be detected is formed between the first common surface and the first detection surface. Herein, the common electrode voltage generating circuit is configured to generate a voltage on the common electrode, as to induce an effective signal voltage on the detection electrode. The detection electrode signal processing circuit includes: a reset voltage time sequence control circuit, a time sequence control circuit for transferring the effective signal voltage on the detection electrode and a differential amplifier. The reset voltage time sequence control circuit is configured to control the detection electrode to reset a voltage. The time sequence control circuit for transferring the effective signal voltage on the detection electrode is configured to transfer an effective signal voltage on the detection electrode. The differential amplifier is configured to output, after performing differential amplification on a reset voltage and the effective signal voltage on the detection electrode, an effective signal used for detecting the film to be detected.

Through the above embodiment, the effective signal used for detecting the film to be detected is output after the differential amplifier is used to perform differential amplification on the reset voltage and the effective signal voltage on the detection electrode, because the differential amplification is performed on an initial output (namely an output during resetting) of the device for detecting the film thickness and a real effective signal output, the influences of environmental factors are eliminated effectively, the technical problem in the related art that the device for detecting the film thickness is easy to be interfered by environments is solved, and the technical effect that the method for detecting the film thickness can avoid environmental interferences is achieved.

In at least one alternative embodiment, in order to make the voltage generated by the common electrode voltage generating circuit accurate, the device for detecting the film thickness of the present disclosure further includes: a common electrode voltage time sequence control circuit, which is configured to generate a control signal; the control signal is used for controlling a voltage amplitude and a voltage width, which are applied to the common electrode by the common electrode voltage generating circuit, to adapt to the detection of a predetermined signal.

In order to control the reset voltage effectively, in at least one alternative embodiment, the detection electrode signal processing circuit further includes: a time sequence control circuit for transferring the reset voltage on the detection electrode, which is configured to, after the detection electrode resets the voltage, transfer the reset voltage on the detection electrode.

When the reset voltage and the effective signal voltage on the detection electrode are transmitted to two input ends of the differential amplifier, several ways may be adopted. In at least one alternative embodiment, in the device for detecting the film thickness of the present disclosure, the detection electrode signal processing circuit further includes: a shifting time sequence control circuit, which is configured to transmit the reset voltage and the effective signal voltage on the detection electrode to the two input ends of the differential amplifier.

In order to improve the fastness of the device for detecting the film thickness, in at least one alternative embodiment, the device for detecting the film thickness of the present disclosure further includes: a common electrode substrate and a detection electrode substrate. The common electrode is set on a first surface of the common electrode substrate, and the first surface of the common electrode substrate is vertical to the first direction, and the common electrode voltage generating circuit is set on a second surface of the common electrode substrate. The detection electrode substrate and the common electrode substrate are set at interval in the first direction. The first surface of the detection electrode substrate faces the first surface of the common electrode substrate, and is parallel to the first surface of the common electrode substrate. The detection electrode is set on the first surface of the detection electrode substrate, and the detection electrode signal processing circuit is set on the second surface of the detection electrode substrate.

In at least one alternative embodiment, in order to further improve the fastness of the device for detecting the film thickness, the device for detecting a film thickness of the present disclosure further includes: a common electrode frame and a detection electrode frame. The common electrode substrate is set on the common electrode frame. The detection electrode frame and the common electrode frame are set at interval in the first direction. The detection electrode substrate is set on the detection electrode frame.

In order to ensure the common electrode and the detection electrode to have superior abrasion resistance and corrosion resistance, in at least one alternative embodiment, the device for detecting the film thickness of the present disclosure further includes: a common electrode protection layer and a detection electrode protection layer. The common electrode protection layer is set on the surface of the common electrode, and the detection electrode protection layer is set on the surface of the detection electrode.

In order to improve the charge induction intensity of the detection electrode, in at least one alternative embodiment, the device for detecting the film thickness of the present disclosure further includes: a common electrode conduction film and a detection electrode conduction film. The common electrode conduction film is set between the common electrode and the common electrode protection layer, and the detection electrode conduction film is set between the detection electrode and the detection electrode protection layer.

It is to be noted that there may be multiple detection electrodes. The multiple detection electrodes are set at intervals along a second direction, wherein the second direction is vertical to a moving direction of the film to be detected, and is vertical to the first direction.

In at least one alternative embodiment, the detection electrode may be an electrode chip, or the detection electrode is a sensor of sensing a charge.

An alternative embodiment of the present disclosure is illustrated below in combination with the accompanying drawings.

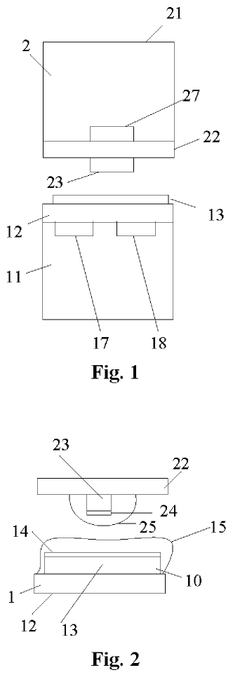

FIG. 1 is a schematic diagram of the device for detecting a film thickness according to the present disclosure. As shown in FIG. 1, the device for detecting the film thickness includes: the common electrode 13, the detection electrode 23, the common electrode voltage generating circuit 17, the common electrode voltage time sequence control circuit 18, and the detection electrode signal processing circuit 27. The common electrode 13 is set at one side of the common electrode substrate 12, and the common electrode voltage generating circuit 17 and the common electrode voltage time sequence control circuit 18 are set at the other side of the common electrode substrate 12. The detection electrode 23 is set at one side of the detection electrode substrate 22, and the detection electrode signal processing circuit 27 is set at the other side of the detection electrode substrate 22. The contents included in the detection electrode signal processing circuit 27 may include the reset voltage, the reset voltage time sequence control circuit, a time sequence for transferring the reset voltage on the detection electrode, a time sequence for transferring the effective signal voltage on the detection electrode, the shifting time sequence control circuit and a differential amplification circuit. The common electrode substrate 12 and the detection electrode substrate 22 are set on the common electrode frame 11 and the detection electrode frame 21 respectively. Herein, after differential amplification is performed, through the differential amplification circuit, on the reset voltage and the effective signal voltage on each electrode in pairs and in order, the voltage is output. The output voltage can eliminate the influences of environmental noises on each electrode, thereby realizing accurate scanning of each electrode. The detection electrode 23 and the common electrode 13 are set oppositely and at interval in the first direction, and the first common surface of the common electrode 13 is opposite to the first detection surface of each detection electrode. The detection channel for the film to be detected is formed between the first common surface and each first detection surface. Actually, there may be multiple detection electrodes in the device for detecting the film thickness, and the multiple detection electrodes are set at interval along the second direction, for example, they are set to 5 DPI, 10 DPI, 50 DPI, 100 DPI, and so on. The detection electrode may also apply a specialized electrode chip. The second direction is vertical to the moving direction of the film to be detected, and is vertical to the first direction.

In order to improve the charge induction intensity of the detection electrode, in an alternative embodiment of the present disclosure, an alternative device for detecting the film thickness is further provided. FIG. 2 is a structure diagram of the common electrode and the detection electrode of the device for detecting the film thickness according to the present disclosure. As shown in FIG. 2, conduction films 14 and 24 are set on the common electrode 13 and the detection electrode 23 respectively. The conduction film is made of a material with high-conductivity, which may be gold and silver, and those skilled in the art may select the proper conduction film according to the actual condition. In order to ensure the common electrode and the detection electrode to have superior abrasion resistance and corrosion resistance, it is needed to coat a protection layer 15 on the surface of the common electrode and the conduction film of the common electrode, and to coat a protection layer 25 on the surface of the detection electrode and the conduction film of the detection electrode. It is preferable that the material of the protection layer has outstanding conductivity, abrasion resistance and corrosion resistance, so as to ensure that the sensitivity of the common electrode and the detection electrode is still high after the electrodes are coated with the protection layers. Those skilled in the art may select the proper material of the protection layer according to the actual condition.

### Embodiment 2

According to another embodiment of the present disclosure, a method for detecting a film thickness is also provided. It is to be noted that the steps presented in the flowchart of the accompanying drawings can be executed in a computer system like a group of computer executable instructions; and moreover, although a logical sequence is shown in the flowchart, in some cases, the presented or described steps can be performed in a sequence different from that described herein. The method for detecting the film thickness of the present disclosure may be used for actuating the device for detecting the film thickness provided by the embodiment of the present disclosure. The method for detecting the film thickness provided by the embodiment of the present disclosure is introduced below.

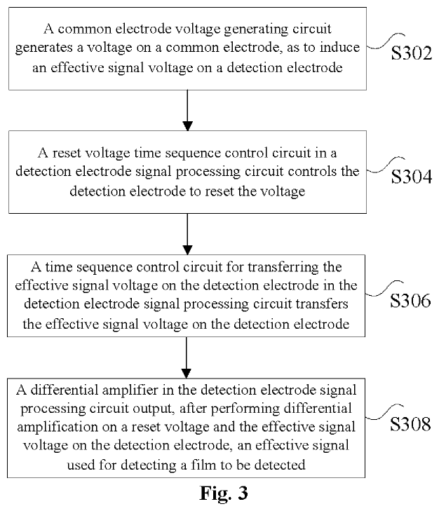

In the embodiment, a method for detecting the film thickness is provided. FIG. 3 is a flowchart of the method for detecting the film thickness according to the present disclosure. As shown in FIG. 3, the method includes the following steps.

At S302, the common electrode voltage generating circuit generates the voltage on the common electrode, as to induce an effective signal voltage on the detection electrode, wherein the common electrode and the detection electrode are set oppositely and at interval in the first direction, the first common surface of the common electrode is opposite to the first detection surface of the detection electrode, and the detection channel for the film to be detected is formed between the first common surface and the first detection surface.

At S304, the reset voltage time sequence control circuit in the detection electrode signal processing circuit controls the detection electrode to reset a voltage.

At S306, the time sequence control circuit for transferring the effective signal voltage on the detection electrode in the detection electrode signal processing circuit transfers the effective signal voltage on the detection electrode.

At S308, the differential amplifier in the detection electrode signal processing circuit outputs, after performing differential amplification on the reset voltage and the effective signal voltage on the detection electrode, the effective signal used for detecting the film to be detected.

Through the steps from S302 to S308, the effective signal used for detecting the film to be detected is output after the differential amplifier is used to perform differential amplification on the reset voltage and the effective signal voltage on the detection electrode, because the differential amplification is performed on the initial output (namely the output during resetting) of the device for detecting the film thickness and the real effective signal output, the influences of environmental factors are eliminated effectively, the technical problem in the related art that the device for detecting the film thickness is easy to be interfered by environments is solved, and the technical effect that the method for detecting a film thickness can avoid environmental interferences Is achieved.

In at least one alternative embodiment, in a situation where there are multiple detection electrodes, when the reset voltage on each detection electrode is transmitted on a falling edge of the time sequence for transferring the reset voltage on the detection electrode, the reset voltage time sequence control circuit controls the reset voltage to reset each detection electrode; it is to be noted that resetting is performed when the reset voltage on each detection electrode is transmitted on the falling edge of the time sequence for transferring the reset voltage on the detection electrode, but it is also feasible to apply the reset voltage for a certain period of time before the falling edge comes, so as to avoid inadequate resetting; when the effective signal voltage on each detection electrode is transmitted on the falling edge of the time sequence for transferring the effective signal voltage on the detection electrode, controlling, the common electrode voltage generating circuit is controlled according to the control signal of the common electrode voltage time sequence control circuit, to apply the voltage to the common electrode; it is to be noted that the common electrode voltage is applied when the effective signal voltage on each detection electrode is transmitted on the falling edge of the time sequence for transferring the effective signal voltage on the detection electrode, but it is also feasible to apply the common electrode voltage for a certain period of time before the falling edge comes, wherein the specific period of the added time may be decided according to the material of the object to be detected.

Signal processing of the method for detecting the film thickness and the time sequence of the signal processing are illustrated below in combination with the accompanying drawings.

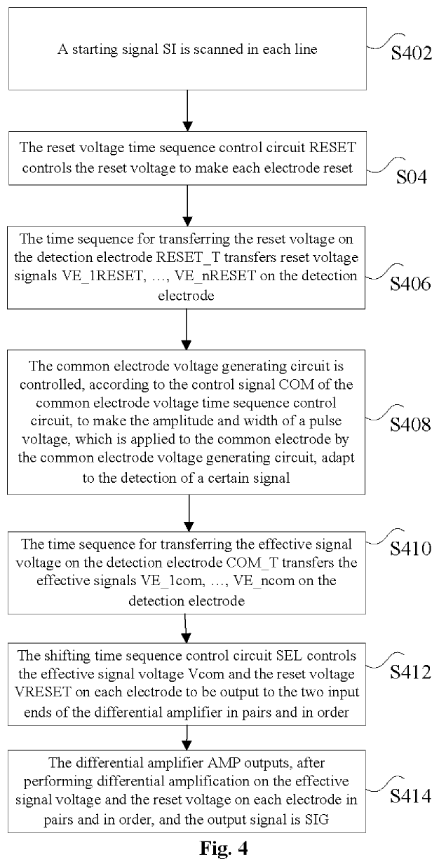

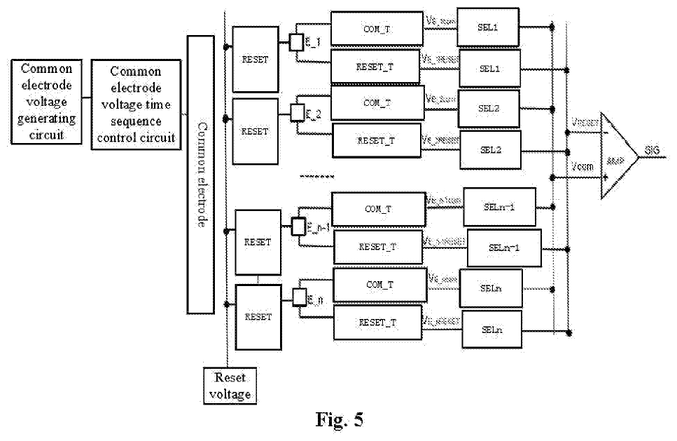

FIG. 4 is a signal processing flowchart of the device for detecting the film thickness according to the present disclosure. As shown in FIG. 4, the flow includes the following steps.

At S402, a starting signal SI is scanned in each line.

At S404, the reset voltage time sequence control circuit RESET controls the reset voltage, as to make each electrode reset.

At S406, the time sequence for transferring the reset voltage on the detection electrode RESET_T transfers reset voltage signals VE_1RESET, . . . , VE_nRESET on the detection electrode.

At S408, the common electrode voltage generating circuit is controlled according to the control signal COM of the common electrode voltage time sequence control circuit, to make the amplitude and width of a pulse voltage, which is applied to the common electrode by the common electrode voltage generating circuit, adapt to the detection of a certain signal.

At S410, the time sequence for transferring the effective signal voltage on the detection electrode COM_T transfers the effective signals VE_1com, . . . , VE_ncom on the detection electrode.

At S412, the shifting time sequence control circuit SEL controls the effective signal voltage Vcom and the reset voltage VRESET on each electrode, to be output to the two input ends of the differential amplifier in pairs and in order.

At S414, the differential amplifier AMP outputs, after performing differential amplification on the effective signal voltage and the reset voltage on each electrode in pairs and in order, wherein the output signal is SIG.

In the steps from S402 to S414, when the device for detecting a film thickness works, firstly, after the starting signal SI is scanned in each line, the reset voltage time sequence control circuit RESET controls the reset voltage, to make each electrode reset; and then, the time sequence for transferring the reset voltage on the detection electrode RESET_T transfers reset voltage signals VE_1RESET, . . . , VE_nRESET on the detection electrode.

FIG. 5 is a signal processing diagram of the device for detecting the film thickness according to the present disclosure. As shown in FIG. 5, the common electrode voltage generating circuit is controlled according to the control signal COM of the common electrode voltage time sequence control circuit, to make the amplitude and width of the pulse voltage, which is applied to the common electrode by the common electrode voltage generating circuit, adapt to the detection of the certain signal. An effective original thickness charge signal is Induced on the detection electrode, and the effective signals VE_1com, . . . , VE_ncom on the detection electrode are transferred through the time sequence for transferring the effective signal voltage on the detection electrode COM_T in the detection electrode signal processing circuit; then, the shifting time sequence control circuit SEL controls the effective signal voltage Vcom and the reset voltage VRESET on each electrode to be output to the two input ends of the differential amplifier in pairs and in order, and the differential amplifier AMP outputs, after performing differential amplification on the effective signal voltage and the reset voltage on each electrode in pairs and in order, and the output signal is SIG. The obtained signal SIG has eliminated the influences of environmental noises on each detection electrode, so the technical problem in the related art that the device for detecting a film thickness is easy to be interfered by environments is solved, and the technical effect that the method for detecting a film thickness can avoid environmental interferences is achieved.

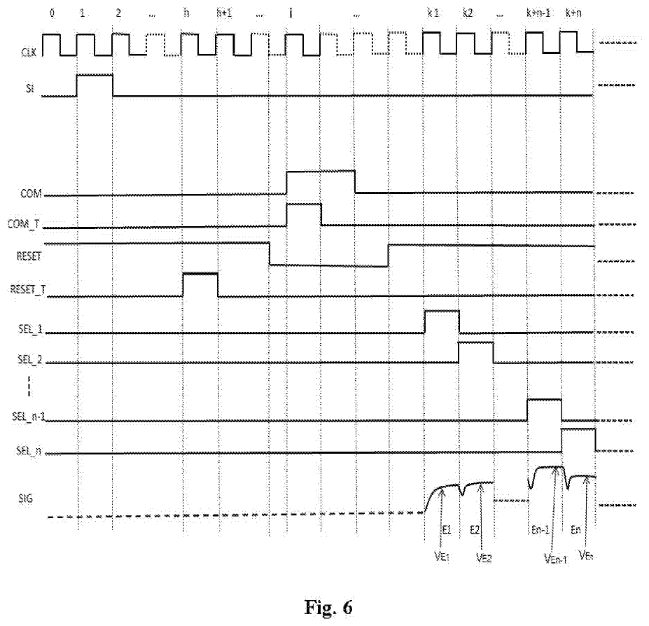

FIG. 6 is sequence diagrams of various signals of the device for detecting the film thickness according to the present disclosure. As shown in FIG. 6, when the device for detecting a film thickness works, after the starting signal SI (the first clock) is scanned in each line, the reset voltage time sequence control circuit RESET controls the reset voltage to make each electrode reset; then, the time sequence for transferring the reset voltage on the detection electrode RESET_T (the hth clock) transfers the reset voltage signals VE_1RESET, . . . , VE_nRESET on the detection electrode; at last, the common electrode voltage generating circuit is controlled, according to the control signal COM of the common electrode voltage time sequence control circuit (from the ith clock, the time of applying the voltage to the common electrode is controlled reasonably, that is, a pulse width of the COM is controlled), to make the amplitude and width of the pulse voltage, which is applied to the common electrode by the common electrode voltage generating circuit, adapt to the detection of the object to be detected. The effective original thickness charge signal is induced on the detection electrode, and the effective signals VE_1com, . . . , VE_ncom on the detection electrode are transferred through the time sequence for transferring the effective signal voltage on the detection electrode COM_T in the detection electrode signal processing circuit; then, the shifting time sequence control circuit SEL (the (k1)th clock, the (k2)th clock, . . . , the (k+n−1)th clock, and the (k+n)th clock) controls the effective signal voltage Vcom and the reset voltage VRESET on each electrode to be output to the two input ends of the differential amplifier in pairs and in order, and the differential amplifier AMP outputs, after performing differential amplification on the effective signal voltage and the reset voltage on each electrode in pairs and in order, and the output signal is SIG (VE1, VE2, . . . , VEn−1, VEn). The obtained signal SIG has eliminated the influences of environmental noises on each detection electrode.

It is to be noted that the reset voltage on each electrode is transmitted on the falling edge of the time sequence for transferring the reset voltage on the detection electrode RESET_T in the embodiment of the present disclosure, so it is necessary to ensure the reset voltage time sequence control circuit RESET to control the reset voltage to reset each electrode at the falling edge of the RESET_T; the effective voltage signal is transmitted on the falling edge of the time sequence for transferring the effective signal voltage on the detection electrode COM_T in the embodiment of the present disclosure, so it is necessary to ensure that the common electrode voltage generating circuit is controlled, according to the control signal COM of the common electrode voltage time sequence control circuit, to apply the voltage on the common electrode at the falling edge of the COM_T; the detection electrode is the sensor of sensing a charge in the embodiment of the present disclosure, so when the detection electrode does not sense an effective thickness signal, it is necessary to ensure that each detection electrode tries to be in a reset state, and ensure that the reset voltage is controlled to reset each electrode for the longest time even the reset voltage time sequence control circuit RESET is in an area out of the time sequence for transferring the effective signal voltage on the detection electrode COM_T and the control signal COM of the common electrode voltage time sequence control circuit. The detection electrode of the device for detecting the film thickness provided by the embodiment of the present disclosure is not limited to a row of detection electrodes, but two or more rows of detection electrodes are also applicable.

The above sequence numbers of the embodiments of the present disclosure are just for describing, instead of representing superiority-inferiority of the embodiments.

In the above embodiments of the present disclosure, the descriptions of the embodiments focus on different aspects. The part which is not described in a certain embodiment in detail may refer to the related description of the other embodiments.

In the several embodiments provided in the application, it should be understood that the technical contents disclosed may be realized in other ways. Herein, the embodiment of the device described above is only schematic; for example, the division of the elements is only a division of logical functions, and there may be other dividing modes during the actual implementation, for example, multiple elements or components may be combined or integrated to another system, or some features may be ignored or are not executed. In addition, coupling, direct coupling, or communication connection shown or discussed may be implemented through indirect coupling or communication connection of some interfaces, elements or components, and may be in an electrical form or other forms.

The elements described as separate parts may be or may not be separate physically. The part shown as the element may be or may not be a physical element, that is to say, it may be in a place or distributed on multiple network elements. It is possible to select, according to the actual needs, part or all of the elements to achieve the objective of the solutions in the present disclosure.

Moreover, all the function elements in the embodiments of the present disclosure may be integrated in a processing element; or the elements exist separately and physically; or two or more than two elements are integrated in an element. The integrated element may be realized in form of hardware or in form of software function element.

If the integrated element is implemented by software function components, and the software function components are sold or used as independent products, they can also be stored in a computer readable storage medium. Based on this understanding, the technical solutions in the embodiments of the present disclosure substantially or the part making a contribution to the traditional art can be embodied in the form of software product; the computer software product is stored in a storage medium and includes a number of instructions to make a computer device (which can be a personal computer, a server or a network device, etc.) perform all or part of the method in each embodiment of the present disclosure. The above storage media include: a USB flash disk, an ROM, an RAM, a mobile hard disk, a magnetic disk or a compact disc, and other media which can store program codes.

The above is only the preferred embodiments of the present disclosure; it should be indicated that, on the premise of not departing from the principles of the present disclosure, those of ordinary skill in the art may also make a number of improvements and supplements, and these improvements and supplements should fall within the scope of protection of the present disclosure.

What is claimed is:

1. A device for detecting a film thickness, comprising: a common electrode, a detection electrode, a common electrode voltage generating circuit, and a detection electrode signal processing circuit; the common electrode and the detection electrode are set oppositely and at interval in a first direction; a first common surface of the common electrode is opposite to a first detection surface of the detection electrode; a detection channel for a film to be detected is formed between the first common surface and the first detection surface; wherein,
the common electrode voltage generating circuit is configured to generate a voltage on the common electrode, as to induce an effective signal voltage on the detection electrode;
the detection electrode signal processing circuit comprises: a reset voltage time sequence control circuit, a time sequence control circuit for transferring the effective signal voltage on the detection electrode and a differential amplifier; wherein, the reset voltage time sequence control circuit is configured to control the detection electrode to reset a voltage; the time sequence control circuit for transferring the effective signal voltage on the detection electrode is configured to transfer the effective signal voltage on the detection electrode; and the differential amplifier is configured to, after performing differential amplification on the reset voltage and the effective signal voltage on the detection electrode, output an effective signal used for detecting the film to be detected.

2. The device as claimed in claim 1, further comprising: a common electrode voltage time sequence control circuit; wherein the common electrode voltage time sequence control circuit is configured to generate a control signal; the control signal is used for controlling a voltage amplitude and a voltage width, which are applied to the common electrode by the common electrode voltage generating circuit, to adapt to a detection of a predetermined signal.

3. The device as claimed in claim 1, wherein the detection electrode signal processing circuit further comprises: a time sequence control circuit for transferring the reset voltage on the detection electrode, configured to, after the detection electrode resets the voltage, transfer the reset voltage on the detection electrode.

4. The device as claimed in claim 1, wherein the detection electrode signal processing circuit further comprises: a shifting time sequence control circuit, configured to transmit the reset voltage and the effective signal voltage on the detection electrode to two input ends of the differential amplifier.

5. The device as claimed in claim 1, further comprising: a common electrode substrate and a detection electrode substrate; wherein,
the common electrode is set on a first surface of the common electrode substrate, the first surface of the common electrode substrate is vertical to the first direction, and the common electrode voltage generating circuit is set on a second surface of the common electrode substrate;
the detection electrode substrate and the common electrode substrate are set at interval in the first direction; a first surface of the detection electrode substrate faces the first surface of the common electrode substrate, and is parallel to the first surface of the common electrode substrate; the detection electrode is set on the first surface of the detection electrode substrate, and the detection electrode signal processing circuit is set on a second surface of the detection electrode substrate.

6. The device as claimed in claim 5, further comprising: a common electrode frame and a detection electrode frame, wherein the common electrode substrate is set on the common electrode frame, the detection electrode frame and the common electrode frame are set at interval in the first direction, and the detection electrode substrate is set on the detection electrode frame.

7. The device as claimed in claim 1, further comprising: a common electrode protection layer and a detection electrode protection layer, wherein the common electrode protection layer is set on a surface of the common electrode, and the detection electrode protection layer is set on a surface of the detection electrode.

8. The device as claimed in claim 7, further comprising: a common electrode conduction film and a detection electrode conduction film, wherein the common electrode conduction film is set between the common electrode and the common electrode protection layer, and the detection electrode conduction film is set between the detection electrode and the detection electrode protection layer.

9. The device as claimed in claim 1, wherein there are multiple detection electrodes; the multiple detection electrodes are set at intervals along a second direction, wherein the second direction is vertical to a moving direction of the film to be detected, and is vertical to the first direction.

10. The device as claimed in claim 9, wherein the detection electrode is an electrode chip, or the detection electrode is a sensor of sensing a charge.

11. A method for detecting a film thickness, comprising:
generating, by a common electrode voltage generating circuit, a voltage on a common electrode, as to induce an effective signal voltage on a detection electrode, wherein the common electrode and the detection electrode are set oppositely and at interval in a first direction, a first common surface of the common electrode is opposite to a first detection surface of the detection electrode, and a detection channel for a film to be detected is formed between the first common surface and the first detection surface;
controlling, by a reset voltage time sequence control circuit in a detection electrode signal processing circuit, the detection electrode to reset a voltage;
transferring, by a time sequence control circuit for transferring the effective signal voltage on the detection electrode in the detection electrode signal processing circuit, an effective signal voltage on the detection electrode;
outputting, by a differential amplifier in the detection electrode signal processing circuit, an effective signal used for detecting a film to be detected after performing differential amplification on the reset voltage and the effective signal voltage on the detection electrode.

12. The method as claimed in claim 11, wherein in a situation where there are multiple detection electrodes,
when the reset voltage on each detection electrode is transmitted on a falling edge of a time sequence for transferring the reset voltage on the detection electrode, controlling, by the reset voltage time sequence control circuit, the reset voltage to reset each detection electrode;
when the effective signal voltage on each detection electrode is transmitted on the falling edge of a time sequence for transferring the effective signal voltage on the detection electrode, controlling, according to a control signal of a common electrode voltage time sequence control circuit, the common electrode voltage generating circuit to apply a voltage to the common electrode.

13. The device as claimed in claim 2, wherein there are multiple detection electrodes; the multiple detection electrodes are set at intervals along a second direction, wherein the second direction is vertical to a moving direction of the film to be detected, and is vertical to the first direction.

14. The device as claimed in claim 3, wherein there are multiple detection electrodes; the multiple detection electrodes are set at intervals along a second direction, wherein the second direction is vertical to a moving direction of the film to be detected, and is vertical to the first direction.

15. The device as claimed in claim 4, wherein there are multiple detection electrodes; the multiple detection electrodes are set at intervals along a second direction, wherein the second direction is vertical to a moving direction of the film to be detected, and is vertical to the first direction.

16. The device as claimed in claim 5, wherein there are multiple detection electrodes; the multiple detection electrodes are set at intervals along a second direction, wherein the second direction is vertical to a moving direction of the film to be detected, and is vertical to the first direction.

17. The device as claimed in claim 6, wherein there are multiple detection electrodes; the multiple detection electrodes are set at intervals along a second direction, wherein the second direction is vertical to a moving direction of the film to be detected, and is vertical to the first direction.

18. The device as claimed in claim 7, wherein there are multiple detection electrodes; the multiple detection electrodes are set at intervals along a second direction, wherein the second direction is vertical to a moving direction of the film to be detected, and is vertical to the first direction.

19. The device as claimed in claim 8, wherein there are multiple detection electrodes; the multiple detection electrodes are set at intervals along a second direction, wherein the second direction is vertical to a moving direction of the film to be detected, and is vertical to the first direction.

20. The device as claimed in claim 13, wherein the detection electrode is an electrode chip, or the detection electrode is a sensor of sensing a charge.
